(19) United States
(12) Patent Application Publication
(10) Pub. No.: US 2011/0090089 A1
(43) Pub. Date: Apr. 21, 2011

(54) METHOD AND APPARATUS FOR DETECTING A FAULT IN A SOLAR CELL PANEL AND AN INVERTER

(76) Inventor: Yuhao Luo, San Jose, CA (US)

(21) Appl. No.: 12/904,965

(22) Filed: Oct. 14, 2010

Related U.S. Application Data
(60) Provisional application No. 61/279,130, filed on Oct. 15, 2009.
(60) Provisional application No. 61/336,200, filed on Jan. 19, 2010.

(51) Int. Cl. G01R 31/26; G06F 19/00; G08B 21/00

(52) U.S. Cl. 340/653; 324/761.01; 702/58

(57) ABSTRACT

A method and apparatus for detecting a fault of a solar panel and an inverter in a solar array includes a monitoring device to detect and to identify a fault of a solar panel and an inverter in a solar array. The method generates a normal operation profile by extracting median values of operation profiles from multiple solar panels in a solar array and then compares an individual operation profile against a normal profile to determine a fault in a solar panel. The method and apparatus can detect a fault in a combination of solar panel and inverter and can identify a fault in an inverter. The method and apparatus can store faulty profiles in a database for particular faults in a solar panel. The method and apparatus can then compare an operation profile from a faulty solar panel with a number of faulty profiles in a database to identify the type of the fault and then generate and report the fault and suggest corrective action.

### CROSS REFERENCE TO RELATED PATENT APPLICATIONS

The instant patent application herein converts and claims priority to U.S. Provisional Patent Application No. 61/279,130 filed on Oct. 15, 2009 to Luo, entitled “Detecting Fault in Solar Panel and Inverter” which is herein incorporated by reference in its entirety. The instant patent application also claims priority to U.S. Provisional Patent Application No. 61/336,200 filed on Jan. 19, 2010 to Luo et al., entitled “A Method of Managing a Photovoltaic System” which is herein incorporated by reference in its entirety.

### FIELD OF THE INVENTION

Embodiments of the present invention generally relate to a method and apparatus for managing a solar array. More specifically, the present invention is directed to a method and apparatus for detecting and identifying a fault of a solar panel and an inverter in a solar array.

### BACKGROUND OF THE RELATED ART

Producing power from solar energy involves installing multiple solar panels and transforming the sun's rays into electricity. Over time, the solar panels and inverters tend to become faulty due to various factors. For example, shading, snow or dust cause fault of the panels' productivity. A faulty inverter may also impair a solar array's power and productivity. As result, a solar panel and inverter requires constant monitoring and maintenance to ensure normal operation.

In general, detecting and correcting a fault of a solar panel and inverter in a solar array can be a very complicated. This particularly occurs when the array has large amount of solar panels. It is even more complicated to locate and identify the type of fault without a physical inspection, which is very costly. There are solutions of detecting fault of array by comparing operation profile with stored reference profile. However, the operation profile is strongly depending on many conditions, such as time, season and climate, which can affect the detection. Due to the complexity of these numerous conditions, the need of reference profiles and the need of generating reference profiles, as well as the comparison with parameters with reference profiles, this process can be very complicated and the result could be inaccurate.

Accordingly, there exists a need for a method and apparatus to conveniently, quickly, and accurately detect a fault of a solar panel and an inverter in a solar array system.

### SUMMARY OF THE INVENTION

The present invention advantageously fills the aforementioned deficiencies by providing a method and apparatus for detecting fault of a solar panel and an inverter in a solar array. The present invention device is unique when compared with other known solutions because the present invention provides:

a monitoring device to detect and identify a fault of a solar panel and an inverter in a solar array;

generation of a normal profile by extracting median values of operation profiles from multiple solar panels in a solar array; comparison of individual operation profile against a normal profile to determine a fault in a solar panel;

detection of a fault in combination of a solar panel and an inverter; and detection of a fault in a solar panel;

identification a fault in an inverter; and the storage of faulty profiles in database for particular faults;

comparison of an operation profile from a faulty solar panel with a number of faulty profiles in a database to identify the type of the fault; and

generation and report of a message with a fault and a suggestion of a corrective action.

The present invention now will be described more fully hereinafter with reference to the accompanying drawings, which are intended to be read in conjunction with both this summary, the detailed description and any preferred and/or particular embodiments specifically discussed or otherwise disclosed. This invention may, however, be embodied in many different forms and should not be construed as limited to the embodiments set forth herein; rather, these embodiments are provided by way of illustration only and so that this disclosure will be thorough, complete and will fully convey the full scope of the invention to those skilled in the art.

According to a first aspect of the present disclosure, there is provided a method of detecting a fault. The method comprises accessing an operation profile of a plurality of solar panels of a solar array and generating a normal profile of a solar panel. The method compares the operation profile from each of the plurality of panels with the normal profile and determines whether the normal profile is different than the operation profile to determine the fault.

In yet another aspect of the present disclosure there is provided an apparatus for detecting a fault comprising a plurality of solar cells forming a solar array and an inverter. The apparatus also has a monitoring device being connected to the solar cells, wherein the monitoring device accesses an operation profile of each of the plurality of solar cells of the solar array. The monitoring device generates a normal profile of a solar cell and compares the operation profile from each of the plurality of panels with the normal profile. The monitoring device determines whether the normal profile is different than the operation profile to determine the fault.

In another embodiment of the present disclosure, there is provided a method of detecting a fault comprising accessing an operation profile of a plurality of solar panels of a solar array, wherein at least one of the plurality of solar panels outputs power over time, and wherein the operation profile of at least one functioning solar panel includes an increasing slope of power over time, a peak, and then a decreasing slope. The method generates a normal profile of a solar panel, and wherein the normal profile outputs power over time, and wherein the normal profile includes an increasing slope of power over time, a peak, and then a decreasing slope. The method compares the operation profile from each of the plurality of panels with the normal profile and determines whether the normal profile is different than the operation profile to determine the fault.

### BRIEF DESCRIPTION OF THE FIGURES

The foregoing and other objects, features and advantages of the invention will be apparent from the following more particular description of preferred embodiments of the invention, as illustrated in the accompanying drawings in which like reference characters refer to the same parts throughout different views. The drawings are not meant to limit the invention to particular mechanisms for carrying out the invention in practice, but rather, the drawings are illustrative of certain ways of performing the invention. Others will be readily apparent to those skilled in the art.

FIG. 1 is a block diagram of a system comprising an apparatus for detecting a fault of a solar panel and an inverter in a solar array according to the present disclosure;

FIG. 2 is a block diagram of a monitoring device for detecting a fault of a solar panel and an inverter in a solar array according to the present disclosure;

FIG. 3 is a flowchart illustrating a method for detecting and reporting a fault of a solar panel and an inverter in a solar array according to the present disclosure;

FIG. 4 is a graph illustrating a method for generating normal profile for a solar panel in a solar array according to the present disclosure; and

FIG. 5 is a flowchart illustrating a method for identifying and reporting a fault of a solar panel and an inverter in a solar array according to the present disclosure.

### DETAILED DESCRIPTION OF THE PREFERRED EMBODIMENTS

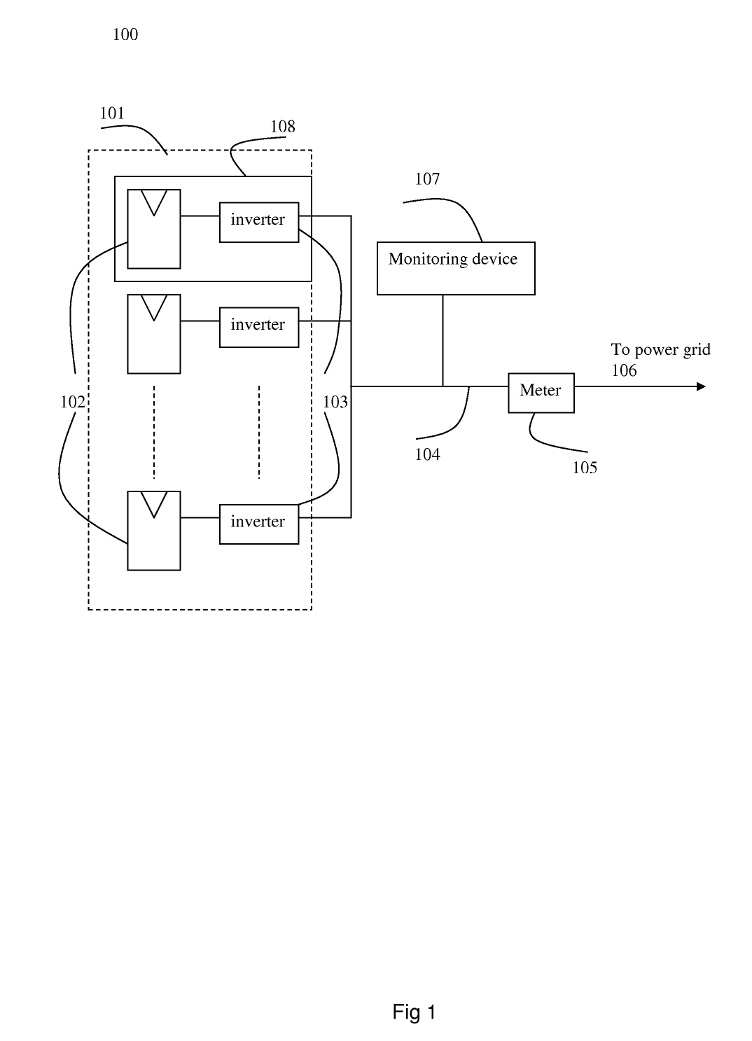

FIG. 1 is a block diagram of a solar energy system 100 comprising apparatus for detecting a fault of a solar panel and an inverter in a solar array 101 according to an embodiment of the present invention. Each solar panel 102 is individually coupled to a DC-AC inverter 103, which converts the DC power generated by the solar panels 102 into AC power. In this enclosure, a solar panel 102 is named “DC solar panel”, while the combination 108 of “DC solar panel” 102 and inverter 103 is named “AC solar panel”. Various configurations are possible and within the scope of the present disclosure. The AC power is supplied to a power grid 106 through a transmission line 104 and a meter 105.

In another embodiment, the DC power generated by the solar panel 102 may be directly utilized without any power conversion. In another embodiment, a DC-DC converter is coupled to each solar panel 102, where the resulting power output of the DC-DC converters may be utilized as DC power or converted to AC power by a single DC-AC inverter. Various configurations are possible and within the scope of the present disclosure.

The AC power collected from the inverters 103 passes through an AC transmission line 104 into the power grid 106. As shown in FIG. 1, the AC transmission line 104 is coupled to a monitoring device 107 for detecting a fault of a solar panels and an inverter 103 in the solar array. In some embodiments, the monitoring device 107 may be coupled to the AC transmission line 104 via a communications network, such as a wireless communication network, Wi-Fi, Wi-Max, a telecommunication protocol, Bluetooth™ or via the Internet.

The monitoring device 107 is configured to obtain an individual operation profiles from multiple AC solar panels 108 in the solar array 101. An individual operation profiles may be any parameter of the AC solar panels 108 over time such as power generated, power used, a voltage over time, and a current over time, heat emitted over time, or any other measurable parameter of the solar panel 108 over time. When there is no fault, the AC solar panels 108 have similar operation profiles, which is similar to their median value. The median value of the operation profiles is named normal profile of the solar panels in the solar array. When a fault happens to a solar panel 108, the operation profile of this panel is significantly different from the normal profile. Significantly different may mean any observable difference from the normal profile, such as a shape of the curve, slope, frequency, amplitude or any other different observable data known in the art to form a decision. The similar procedure can be applied to DC solar panel 102 as well.

In alternative embodiments, the monitoring device 107 may perform additional processing of profiles to identify and provide the particular type, cause and corrective action of a fault. The monitoring device 107 compares the operation profiles of the solar panels 102 against corresponding normal profile to identify a fault of the solar panels. Possible causes of a fault of the solar panel include a buildup of precipitation, a faulty inverter, shading, or a broken damage, among other defects.

Additionally and/or alternatively, power data may be obtained by the inverters 103. Data can be then provided to the monitoring device 107. In some embodiments, the monitoring device 107 may obtain power data directly from solar panels. In some embodiments, power data may be obtained by a device coupled to the solar panel 102 and transmitted to the monitoring device 107 via a communication network, such as the Bluetooth or Internet.

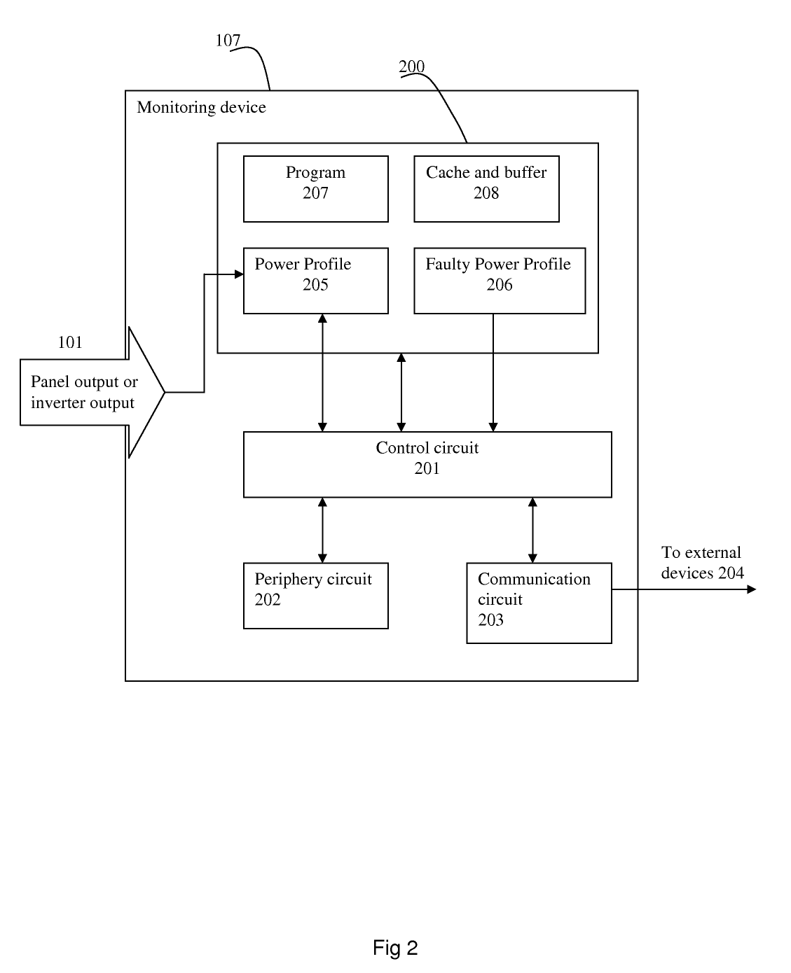

FIG. 2 is a block diagram of a monitoring device 107 for detecting a fault of a solar panel and an inverter in a solar array according to the present disclosure. Monitoring device 107 preferably comprises a computer device having a number of components. The outputs of solar panels 102 or outputs of inverters 103 are coupled to the monitoring device 107. The monitoring device 107 includes a memory 200, a control circuit 201, periphery circuits 202, and communication circuit 203. The monitoring device 107 may comprise different components than those discussed herein as the instant disclosure shows only a preferred embodiment. The memory may include, but is not limited to, an operation profile database, and a faulty profile database, a cache and a buffer, as well as a number of program instructions that include an operating system. The memory 200 may comprise RAM (random access memory), ROM (read only memory), flash memory, or the like, and any combination thereof. The control circuit may include, but not limited to, a processor, a DSP (digital signal processor), a CPU, and a LUT (lookup table). The periphery circuits 202, which support operation of the control circuit 200, may include, but are not limited to, I/O interfaces, a cache, a power supply, a clock circuits, and a data register.

According to one embodiment, the monitoring device 107 comprises a Programmable Logic Device, including FPGA (Field Programmable Gate Array), CPLD (Complex Programmable Logic Device), or the like.

In an embodiment of the present disclosure, the monitoring device 107 may comprise a general purpose computer. Turning now to FIG. 2, the communication device 203 may be connected to a network device 204 that can be any device connected to, or associated with a computer or communication device operable with a software program. In one preferred embodiment, the network device can be an internet appliance, a memory, a computing device or any other device known in the art.

The computer system preferably includes the generic components of most general purpose computers. The computer system comprises an interconnection mechanism such as a bus or circuitry which couples an input device such as a keyboard. The system also has a processor 201 (such as a microprocessor having an arithmetic logic unit, a register and a control unit). The computer also includes a storage device or memory (such as a computer disk for a main memory and secondary storage) and an output device such as a monitor or screen. The computer also has a network connection for connecting to the Internet. Various embodiments of the invention will be described in conjunction with the components of computer systems. A typical example of a computer system is an IBM ®Personal Computer, an APPLE® MAC® computer, or a compatible computer.

According to one embodiment, the control circuit is configured to analyze operation profiles of solar panels 102 in a solar array 101 to generate a normal profile.

According to one embodiment, the control circuit is configured to compare operation profiles against the normal profile to determine whether a fault of the solar panel 108 exists.

In another embodiment, the control circuit 202 may be further configured to generate an alert (e.g., a warning message, or alarm) upon detecting a fault. Alert can be any audible signal known in the art.

Furthermore, the detected fault from a solar panel and an inverter are analyzed to identify the type of fault. For example, if an operation profile from output of inverter shows a decrease from normal production to almost zero production, while the operation profile from solar panel shows a normal profile, then it is determined that the inverter is faulty.

In another embodiment, the control circuit 201 may be further configured to identify the type of fault. When an operation profile of the solar panel 102 is compared to a corresponding normal profile, certain characteristics of the difference between the profiles (e.g., a magnitude, a slope, a turning point, and the like) may indicate a specific type of fault. For example, if a power production profile shows a decrease from normal production to almost zero production for a short period of time and come back to normal, an object may be blocking the sun at a particular time of day.

In another embodiment, the control circuit 202 may further identify a particular cause of fault, and may suggest a corrective action, or even automatically correct the fault. It should be appreciated that the solar panel 108 may comprise a motor or the like for removing, installing, rotating, connecting, disconnecting or for turning the solar panel 108 into the sun's rays.

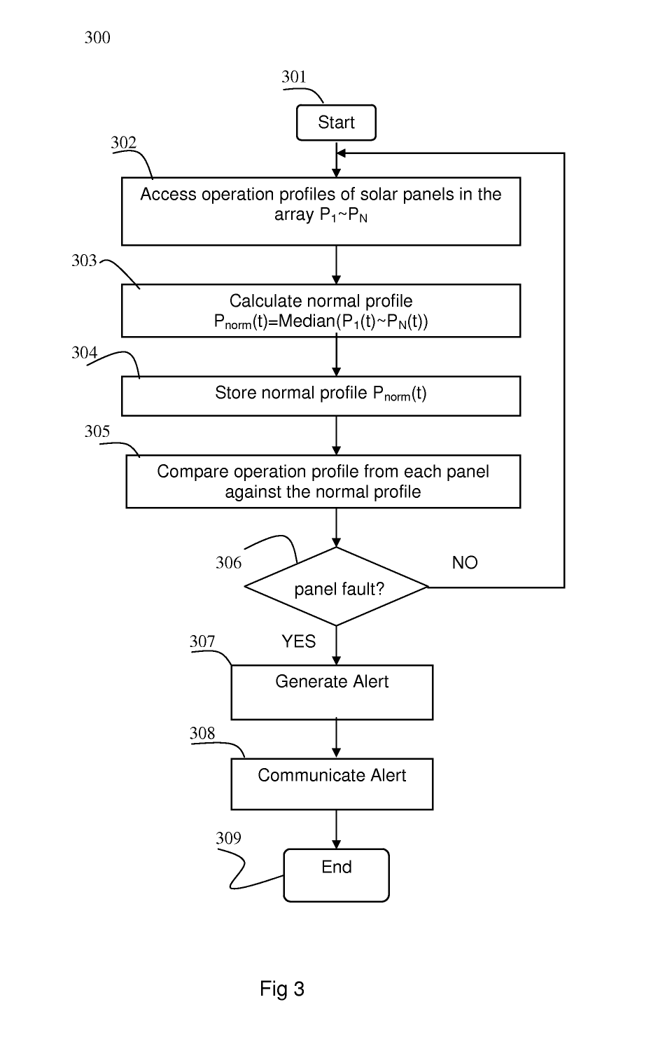

FIG. 3 is a flowchart illustrating a method 300 for detecting a fault of a solar panel in a solar array, including generating and storing a normal profile. It should be appreciated that some steps may be performed in a different order than shown or alternatively, some steps may be performed at the same time. Various configurations are possible and within the scope of the present disclosure.

The method 300 starts at step 301, and proceeds to step 302, where an operation profile of all solar panels of a solar array is accessed. At step 303, the profiles are analyzed to generate the normal profile of the solar panel in this array.

At step 304, the operation profile from each panel is compared with the normal profile of the corresponding solar array. If the operation profile is similar to the normal profile, it is determined that no fault exists (option “NO”), and the method 300 returns to step 302. Similar means that in one embodiment a graph of power over time shares data attributes. However, if a significant difference exists between the operation profile and normal profile, it is determined that a fault exists in the solar panel (option “YES”), and the method 300 proceeds to step 307. Different means that in one embodiment a graph of power over time includes different data attributes (slope, amplitude, frequency, shape of curve etc.). At step 307 an alert message is generated to indicate that a fault has been detected for a solar panel. At step 308 the alert is communicated to external devices 204, such as a display, or a server. Then method 300 proceeds to 309 and ends.

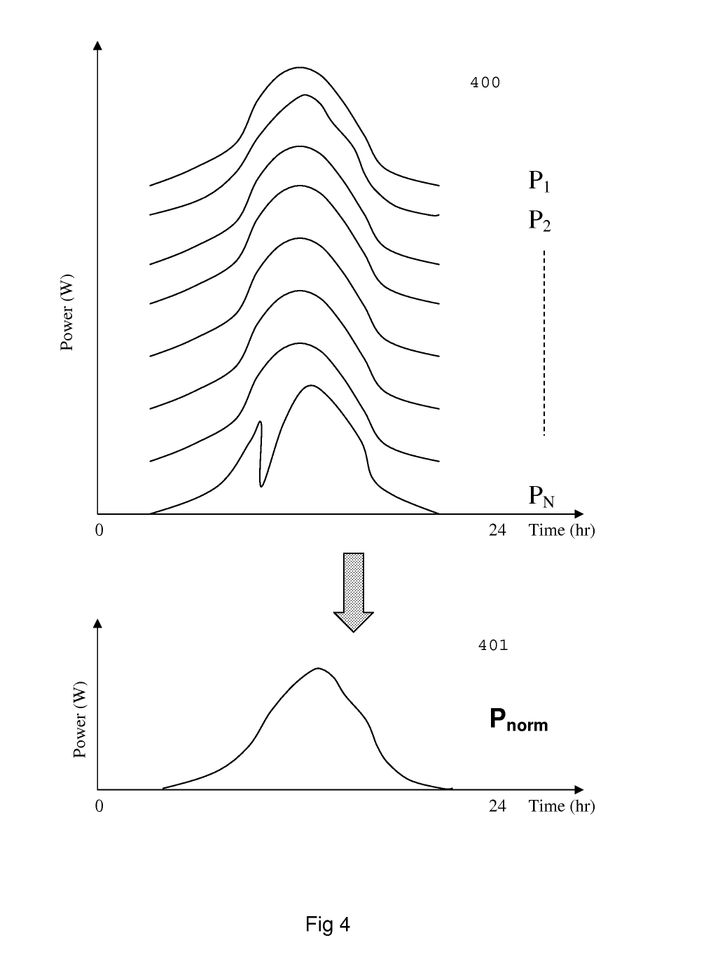

FIG. 4 is a graph illustrating generating normal profile for a solar array with N number of solar panels according to the present disclosure. The graph 400 represents the operation profiles P1, P2, . . . PN from individual solar panels in the solar array for a typical day with 24 hours. It should be appreciated that the graph may include different time amounts or time intervals such as 12 hours, 6 hours, 48 hours, 1 hour, twenty minutes and any time interval known in the art and the intervals shown form no limitations to the present disclosure.

As all the solar panels are similar and are also under the similar climate conditions (such as solar radiation, temperature, and wind), the solar panels show similar operation profile under normal operation. A faulty solar panel will show significant different profile. However, as the chance of 50% of the total amount of panels in the array have fault at the same time is negligible, the median value of the operation profiles is always similar to the operation profile of a normal panel. The median values of power at all time points in the profile are extracted and form a new profile 401, which is named as the normal profile of the array Pₙₒᵣₘ and stored in the memory. In this example, the profile of the Nth panel shows a reduction in power for a short time and then an increase back to normal. As can be seen the slope increases and then markedly decreases and the increases steeply a second time to the peak level and then the slope decreases. This is compared to the normal profile that includes an increasing slope then a peak then a decreasing slope. When compared to the normal profile Pₙₒᵣₘ 401, the reduction in the power of the Nth panel is statistically significant, thereby indicating a fault of the solar panel. It should be appreciated that other parameters may be reviewed to determine the difference not discussed herein such as frequency, amplitude, slope, and any other relevant data associated with the graph of power over time.

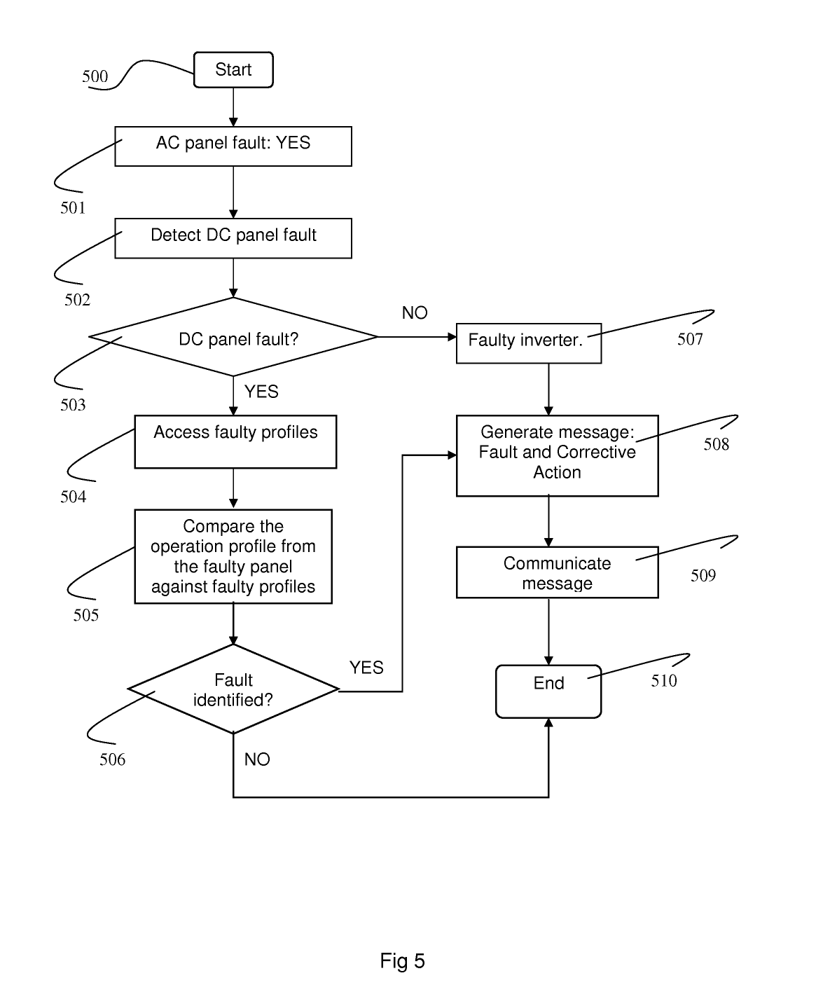

FIG. 5 is a flowchart illustrating a method for identifying and reporting a fault of a solar panel and an inverter in a solar array according to the present disclosure. It should be appreciated that some steps may be performed before others or some steps can be performed at the same time and the method is not limited to the exact configuration discussed herein. Various configurations are possible and within the scope of the present disclosure.

The method 500 starts and proceeds to step 501. At step 501, a fault is detected in an AC panel 108, which comprises a DC solar panel 102 and an inverter 103 and optionally other components omitted for brevity. If an AC panel 108 shows a fault, then at step 502 the DC panel 102 is detected for a fault following method 300 previously discussed above. In step 503, if a fault is not detected in the DC panel (option “NO”), then it is determined that there is a faulty inverter and the method 500 proceeds to 507. At step 508 a message is generated to indicate the type of fault and some optional corrective action. At step 509 the message is communicated to an external device 204, such as a display, or a server, or to a servicer. Then, the method 500 proceeds to step 510 and the method 500 ends.

In step 503, if a fault is detected in the DC panel (option “YES”), the method 500 proceeds to step 504 to access the faulty profiles stored in a memory corresponding to particular known faults. In step 505, an operation profile from a faulty DC panel is compared to the faulty profiles. If there is no similar profile in the faulty profiles to the operation profile, then the fault could not be identified.

Method 500 then proceeds to step 510 and the method 500 ends. If a similar profile is found in the number of faulty profiles, then the fault is determined in step 506 (option “YES”). Method 500 then proceeds to step 508, in which a message is generated to indicate the type of fault and some optional corrective action. At step 509 the message is then communicated to the external devices 204, such as a display, or a server. Then, the method 500 proceeds to step 510 and the method 500 ends.

Generally, in operation, the computer system operable with that method shown in FIGS. 1-5 is controlled by an operating system. Typical examples of operating systems are MS-DOS, Windows95, 98, 2000, XP, Vista and Windows 7 from Microsoft Corporation, or Solaris and SunOS from Sun Microsystems, Inc., UNIX based operating systems, LINUX based operating systems, or the Apple OSX from Apple Corporation. As the computer system operates, input such as input search data, database record data, programs and commands, received from users or other processing systems, are stored on storage device. Certain commands cause the processor to retrieve and execute the stored programs. The programs executing on the processor may obtain more data from the same or a different input device, such as a network connection. The programs may also access data in a database for example, and commands and other input data may cause the processor to index, search and perform other operations on the database in relation to other input data. Data may be generated which is sent to the output device for display to the user or for transmission to another computer system or device. Typical examples of the computer system are personal computers and workstations, hand-held computers, dedicated computers designed for a specific purpose, and large main frame computers suited for use many users. The present invention is not limited to being implemented on any specific type of computer system or data processing device.

It is noted that the present invention may also be implemented in hardware or circuitry which embodies the logic and processing disclosed herein, or alternatively, the present invention may be implemented in software in the form of a computer program stored on a computer readable medium such as a storage device. In the later case, the present invention in the form of computer program logic and executable instructions is read and executed by the processor and instructs the computer system to perform the functionality disclosed as the invention herein. If the present invention is embodied as a computer program, the computer program logic is not limited to being implemented in any specific programming language. For example, commonly used programming languages such as C, C++, JAVA as well as others may be used to implement the logic and functionality of the present invention. Furthermore, the subject matter of the present invention is not limited to currently existing computer processing devices or programming languages, but rather, is meant to be able to be implemented in many different types of environments in both hardware and software.

Furthermore, combinations of embodiments of the invention may be divided into specific functions and implemented on different individual computer processing devices and systems which may be interconnected to communicate and interact with each other. Dividing up the functionality of the invention between several different computers is meant to be covered within the scope of the invention.

While this invention has been particularly shown and described with references to a preferred embodiment thereof, it will be understood by those skilled in the art that is made therein without departing from the spirit and scope of the invention as defined by the following claims.

What is claimed is:

1. A method of detecting a fault comprising:
accessing an operation profile of a plurality of solar panels of a solar array;
generating a normal profile of a solar panel;
comparing the operation profile from each of the plurality of panels with the normal profile; and
determining whether the normal profile is different than the operation profile to determine the fault.

2. The method of claim 1, further comprising determining whether the normal profile is significantly different in power over time from the operation profile and then determining that the fault exists in the solar panel.

3. The method of claim 2, further comprising generating an audible alarm to indicate that the fault is detected for the solar panel.

4. The method of claim 3, further comprising communicating the fault to an external device.

5. The method of claim 4, further comprising communicating the fault to at least one of a display, a remote device, a local entity, a servicer, a manufacturer, a computer, or a server.

6. The method of claim 1, further comprising determining whether the normal profile is different from the operation profile in terms of a curve generated by power generated by the solar panel over time; and
determining that the fault exists in the solar panel.

7. The method of claim 1, further comprising detecting the fault using a monitoring device being disposed between at least one solar panel and a meter.

8. The method of claim 1, further comprising generating the normal profile by a median profile; and
wherein the median profile is generated from power generated by each solar panel of the plurality of solar panels in the array over time.

9. The method of claim 8, further comprising storing the normal profile in a memory.

10. The method of claim 1, further comprising determining whether the normal profile is different than the operation profile to determine the fault by analyzing power generated by the solar panel over time; and
determining the fault when a slope of the operation profile over time is different than a slope of the normal profile over time.

11. The method of claim 1, further comprising determining whether the normal profile is different than the operation profile to determine the fault by analyzing power generated by the solar panel over time; and
determining the fault when an amplitude of the operation profile is different than an amplitude of the normal profile.

12. The method of claim 1, further comprising detecting an AC panel fault or detecting a DC panel fault.

13. The method of claim 12, further comprising indicating a faulty inverter when detecting the DC panel fault.

14. The method of claim 1, further comprising accessing the operation profile of more than two solar panels of the solar array.

15. An apparatus for detecting a fault comprising:
a plurality of solar cells forming a solar array;
an inverter;
a monitoring device being connected to the solar cells, wherein the monitoring device accesses an operation profile of each of the plurality of solar cells of the solar array;
the monitoring device generating a normal profile of a solar cell;
the monitoring device comparing the operation profile from each of the plurality of panels with the normal profile; and
the monitoring device determining whether the normal profile is different than the operation profile to determine the fault.

16. The apparatus of claim 15, wherein the monitoring device determines whether the normal profile is significantly different from the operation profile of each solar cell; and wherein the monitoring device determines that the fault exists in the solar cell.

17. The apparatus of claim 16, further comprising an alarm for generating an audible alarm to indicate that the fault is detected for the solar cell.

18. The apparatus of claim 17, further comprising a communication device for communicating the fault to an external device.

19. The apparatus of claim 18, wherein the communication device communicates the fault to at least one of a display, a remote device, a local entity, a remote entity, a servicer, a manufacturer, a computer, a wireless transceiver, or a server.

20. The apparatus of claim 15, wherein the monitoring device comprises a control circuit, the control circuit determining whether the normal profile is different from the operation profile in terms of a curve generated by power generated by the solar cell over time, wherein the control circuit then determines that the fault exists.

21. The apparatus of claim 15, further comprising a meter, and wherein the monitoring device is disposed between the solar cells and the meter.

22. The apparatus of claim 15, wherein the monitoring device generates the normal profile using a median profile, wherein the median profile is generated from power generated by each solar cell of the plurality of solar cells over time.

23. The apparatus of claim 22, further comprising a memory, and wherein the normal profile is stored in the memory.

24. The apparatus of claim 15, wherein the monitoring device determines whether the normal profile is different than the operation profile to determine the fault by analyzing power generated by the solar cell over time; and
wherein the monitoring device determines the fault when a slope of the operation profile is different than a slope of the normal profile.

25. The apparatus of claim 15, wherein the monitoring device determines whether the normal profile is different than the operation profile to determine the fault by analyzing power generated by the solar cell over time; and
wherein the monitoring device determines the fault when an amplitude of the operation profile is different than an amplitude of the normal profile.

26. The apparatus of claim 15, wherein the monitoring device determines an AC panel fault or a DC panel fault.

27. The apparatus of claim 26, wherein the monitoring device determines that a faulty inverter is present when detecting the DC panel fault.

28. The apparatus of claim 27, wherein the monitoring device accesses the operation profile of more than two solar cells of the solar array.

29. A method of detecting a fault comprising:
accessing an operation profile of a plurality of solar panels of a solar array, wherein at least one of the plurality of solar panels generates power over time, and wherein the operation profile of at least one functioning solar panel includes an increasing slope of power over time, a peak, and then a decreasing slope;
generating a normal profile of the solar panels of the solar array, and wherein the normal profile outputs power over time, and wherein the normal profile includes an increasing slope of power over time, a peak, and then a decreasing slope; and
comparing the operation profile from each of the plurality of panels with the normal profile; and
determining whether the normal profile is different than the operation profile to determine the fault.

30. The method of claim 29, wherein the fault is detected by a monitoring device comprising at least one of a controller, a memory, a communication circuit and a bus.
